(19) United States
(12) Patent Application Publication
(10) Pub. No.: US 2026/0223511 A1
(43) Pub. Date: Jul. 30, 2026

(54) DISPLAY APPARATUS

(71) Applicant: SAMSUNG ELECTRONICS CO., LTD., Suwon-si (KR)

(72) Inventors: Dohoon KIM, Yokohama-shi (JP); Dai AOKI, Yokohama-shi (JP); Eiji HASEGAWA, Yokohama-shi (JP)

(73) Assignee: SAMSUNG ELECTRONICS CO., LTD., Suwon-si (KR)

(21) Appl. No.: 19/578,438

(22) Filed: Mar. 25, 2026

Related U.S. Application Data
(63) Continuation of application No. PCT/KR2024/014741, filed on Sep. 27, 2024.

(30) Foreign Application Priority Data
Sep. 27, 2023 (JP) 2023-164702

(51) Int. Cl. H10H 29/85; H10H 29/24; H10H 29/80

(52) U.S. Cl. CPC H10H 29/8517; H10H 29/24; H10H 29/8421

(57) ABSTRACT

Provided is a display device including a light emitting element array substrate including a plurality of light emitting elements, a color conversion structure on the light emitting element array substrate, and a bonding unit between the light emitting element array substrate and the color conversion structure, wherein the color conversion structure includes a transparent substrate, partition walls between pixel regions of a plurality of color pixels and on the transparent substrate, a color conversion layer in at least one pixel region of the pixel, the color conversion layer being configured to convert light incident on the at least one pixel region into a color corresponding to a color pixel in the at least one pixel region, a light transmissive resin layer on the color conversion layer, and a reflective layer on the light transmissive resin layer, the reflective layer including openings corresponding to each color pixel of the plurality of color pixels and configured to guide light from the light emitting elements into the partition walls.

### CROSS-REFERENCE TO RELATED APPLICATIONS

This application is a bypass continuation of International Application No. PCT/KR2024/014741, filed on Sep. 27, 2024, which is based on and claims priority to Japan Patent Application No. 2023-164702, filed on Sep. 27, 2023, in the Japan Intellectual Property Office, the disclosures of which are incorporated by reference herein in their entireties.

### BACKGROUND

### 1. Field

Embodiments of the present disclosure relate to a display device.

### 2. Description of Related Art

As display devices, while liquid crystal display (LCD) displays and organic light emitting diode (OLED) displays are widely used, recently display devices using micro light emitting diodes (LEDs) as light emitting elements have been attracting attention. A display device using micro LEDs is a next-generation display device that has fast response speed, does not cause burn-in, and may project high-brightness, high-quality images with low power consumption.

Among micro LED display devices, there are full-color display devices having a structure that converts the color of light emitted from micro LEDs and emits it to the outside. Such a full-color display device has a structure in which a light emitting element array substrate having a plurality of micro LEDs and a color conversion panel having a color conversion layer are bonded and integrated. The color of light that has passed through the color conversion layer is, e.g., red, green, or blue, and light of each color is emitted to the outside to realize full-color display.

Further, a display device has a configuration in which a color conversion layer having phosphors is disposed on blue micro LEDs, with a reflective structure disposed on a lower surface of the color conversion layer and a dichroic filter disposed on an upper surface.

A display device of a self-luminous type in which an array substrate mounting self-luminous elements such as micro LEDs is bonded to a color conversion layer may be configured such that light emitted from the light emitting elements passes through the color conversion layer and is emitted to the outside.

However, in such a display device, light loss may occur due to backward reflected light where a portion of the light emitted from the light emitting elements is reflected from a surface of the color conversion layer. Further, in such a conventional display device, light loss may occur due to backward emission where a portion of the color-converted light that has passed through the color conversion layer emits toward the light emitting element side.

In a display device, reducing such light loss is a very important enhancement because it leads to enhancement in luminous efficiency and brightness in the color conversion layer, and also enables reduction of power consumption. However, conventional display devices have insufficient measures against such light loss, and there is room for enhancement.

The above-described information may be provided as related art for the purpose of helping understanding of the disclosure. No claim or determination is made as to whether any of the foregoing is applicable as background art in relation to the disclosure.

### SUMMARY

One or more embodiments provide a display device capable of reducing light loss of emission light emitted from light emitting elements or color-converted light that has passed through a color conversion layer, thereby implementing enhancement in luminous efficiency and low power consumption.

However, the objects of the disclosure are not limited to the problems mentioned above, and may be determined in various ways without departing from the spirit and scope of the disclosure.

According to an aspect of an embodiment, there is provided a display device including a light emitting element array substrate including a plurality of light emitting elements, a color conversion structure on the light emitting element array substrate, and a bonding unit between the light emitting element array substrate and the color conversion structure, wherein the color conversion structure includes a transparent substrate, partition walls between pixel regions of a plurality of color pixels and on the transparent substrate, a color conversion layer in at least one pixel region of the pixel, the color conversion layer being configured to convert light incident on the at least one pixel region into a color corresponding to a color pixel in the at least one pixel region, a light transmissive resin layer on the color conversion layer, and a reflective layer on the light transmissive resin layer, the reflective layer including openings corresponding to each color pixel of the plurality of color pixels and configured to guide light from the light emitting elements into the partition walls.

A size of at least one opening of the openings may be equal to or greater than a size of the light emitting element in a plan view.

The reflective layer may include at least one of Al—Al alloy, Ag—Ag alloy, Cu—Cu alloy, Pd—Pd alloy, Rh, TiO₂ mixed resin, and Al₂O₃ mixed resin.

A transmittance of the light transmissive resin layer may be greater than or equal to 70% and less than or equal to 100%.

A light transmissive resin mixed with light diffusion particles may fill the pixel region corresponding to the blue pixel.

An inner circumferential surface of at least one partition wall of the partition walls may include a reflective portion that includes at least one of Al—Al alloy, Ag—Ag alloy, Cu—Cu alloy, Pd—Pd alloy, Rh, TiO₂ mixed resin, and Al₂O₃ mixed resin.

An optical functional layer including at least one of an overcoat layer having a refractive index greater than or equal to 1.0 and less than or equal to 1.3 and an air layer is between the color conversion layer and the transparent substrate.

The reflective layer may be spaced apart from the pixel region of the blue pixel in a horizontal direction.

A first optical filter may be between the color conversion layer and the light emitting element, the first optical filter being configured to transmit blue light and reflect green light and red light.

A second optical filter may be between the color conversion layer and the transparent substrate, the second optical filter being configured to reflect blue light and transmit green light and red light.

The color conversion layer and the light transmissive resin layer may be in the pixel region partitioned by the partition walls corresponding to at least one pixel among each color pixel.

A height of at least one partition wall of the partition walls may be greater than or equal to 5 μm and less than or equal to 50 μm, and a thickness of the light transmissive resin layer may be greater than or equal to 2 μm and less than or equal to 20 μm.

The light emitting element may be a micro light emitting diode (LED).

### BRIEF DESCRIPTION OF DRAWINGS

The above and other aspects and features of the present disclosure will become more apparent by describing in detail exemplary embodiments thereof with reference to the attached drawings, in which:

FIG. 1 is a cross-sectional view illustrating a display device according to a first embodiment;

FIG. 2 is a view illustrating the color conversion structure of the display device according to the first embodiment as viewed from the reflective surface side;

FIG. 3 is a cross-sectional view illustrating a display device according to a second embodiment;

FIG. 4 is a view illustrating the color conversion structure of the display device according to the second embodiment as viewed from the reflective surface side;

FIG. 5 is a cross-sectional view illustrating a display device according to a third embodiment;

FIG. 6 is a view illustrating the color conversion structure of the display device according to the third embodiment as viewed from the reflective surface side;

FIG. 7 is a cross-sectional view illustrating a display device according to a fourth embodiment;

FIG. 8 is a view illustrating the color conversion structure of the display device according to the fourth embodiment as viewed from the reflective surface side;

FIG. 9 is a cross-sectional view illustrating a display device according to a fifth embodiment;

FIG. 10 is a view illustrating the color conversion structure of the display device according to the fifth embodiment as viewed from the reflective surface side;

FIG. 11 is a cross-sectional view illustrating a display device according to a sixth embodiment;

FIG. 12 is a view illustrating the color conversion structure of the display device according to the sixth embodiment as viewed from the reflective surface side;

FIG. 13 is a table showing test results of embodiments and related embodiments in performance tests; and

FIG. 14 is a graph illustrating test results of embodiments and related embodiments in performance tests.

### DETAILED DESCRIPTION

Hereinafter, embodiments of the present invention are described in detail with reference to the attached drawings. In the drawings below, like reference numerals designate like components, and the size of each component in the drawings may be exaggerated for clarity and convenience of description. The embodiments described below are merely exemplary, and various modifications are possible from these examples.

Hereinafter, when described as “upper portion” or “above,” it may include not only being directly above in contact but also being above without contact. Similarly, when described as “lower portion” or “below,” it may include not only being directly below in contact but also being below without contact.

A singular expression includes plural expressions unless the context clearly indicates singularity. Further, when a portion “includes,” “includes,” or “has” a certain component, these mean that it may further include other components without excluding other components unless specifically stated otherwise.

Regarding steps constituting a method, unless an order is clearly described or there is a contrary description, the steps are performed in an appropriate order. The steps are not necessarily limited as being performed in the mentioned order. The use of all examples or exemplary terms is merely for describing technical ideas, and unless limited by the claims, the scope is not limited by the examples or exemplary terms.

In each drawing, axes parallel to two orthogonal sides of the transparent substrate of the display device according to the embodiment are referred to as an X-axis and a Y-axis, respectively, and a direction orthogonal to the X-axis and Y-axis is referred to as a Z-axis. Further, a direction along the X-axis is referred to as an X direction, a direction along the Y-axis is referred to as a Y direction, and a direction along the Z-axis is referred to as a Z direction. However, each direction does not limit the direction when the display device is used, and the direction when the display device is used is arbitrary.

Further, in the following description, the ordinal numbers, such as “first” and “second,” are used for convenience, and do not define any specific order, unless otherwise specified.

A display device 100 according to a first embodiment is described.

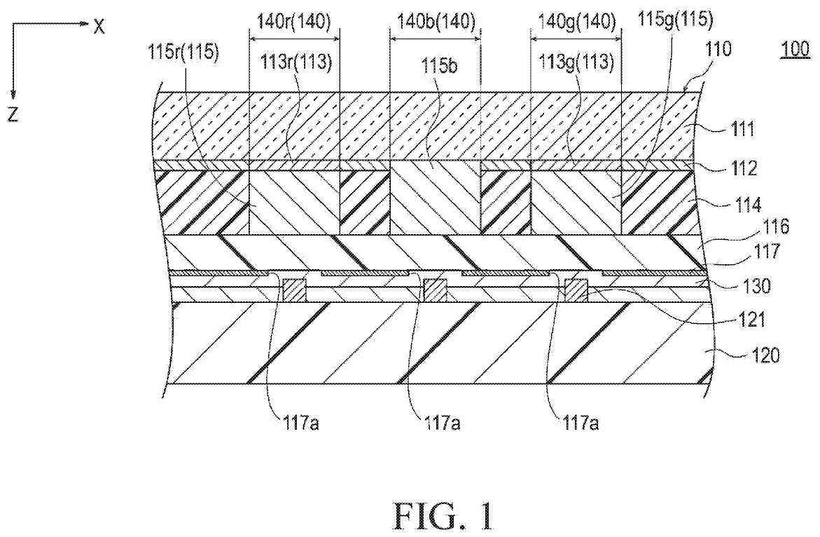

The display device 100 includes a color conversion structure 110, a light emitting element array substrate 120, and a bonding unit 130 as illustrated in FIG. 1. The color conversion structure 110 and the light emitting element array substrate 120 are bonded through the bonding unit 130 in a state of being vertically aligned (aligned in the Z direction) by the bonding unit 130.

The color conversion structure 110 includes a transparent substrate 111, a light-shielding matrix 112, color filters 113 (a red color filter 113r, a green color filter 113g), partition walls 114, color conversion layers 115 (a red conversion layer 115r, a green conversion layer 115g), a light transmissive resin layer 116, and a reflective layer 117.

The transparent substrate 111 is formed of a transparent material having light transmissivity, such as a glass material or a resin material such as polyimide. Particularly in the case of a resin material, the transparent substrate 111 may be in a flexible film shape.

The light-shielding matrix 112 is composed of a patternable light-shielding material. The light-shielding matrix 112 may be black and may have no light transmissivity (or very low light transmissivity) and is referred to as a black matrix. The light-shielding matrix 112 separates each pixel on a pixel-by-pixel basis. Further, the light-shielding matrix 112 does not have to be formed.

The color filter 113 is composed of the red color filter 113r and the green color filter 113g. The color filter 113 suppresses light of wavelengths other than each color component included in light emitted from the light emitting elements (micro LEDs) 121. Thereby, the display device 100 enhances color purity and enables clear color reproduction. Further, the color filter 113 does not have to be formed.

The partition walls 114 individually partition each color pixel corresponding to the light emitting elements 121. A region partitioned by the partition walls 114 adjacent in the X direction or Y direction functions as pixel regions 140 (a red pixel region 140r, a green pixel region 140g, a blue pixel region 140b) of each color pixel that becomes a subpixel. The color conversion layers 115 (the red conversion layer 115r, the green conversion layer 115g), a light transmissive layer 115b, etc. may be formed in the pixel regions 140. A height of the partition walls 114 in the vertical direction (Z direction) is 5 μm or more and 50 μm or less.

As a forming material of the partition walls 114, e.g., photosensitive resins such as acrylic resins, epoxy resins, silicone resins, and polyimide resins may be suitably used.

The color conversion layer 115 is formed in at least one of the pixel regions 140 of each color pixel and converts light incident on the pixel region 140 into a color corresponding to each color pixel. The color conversion layer 115 includes the red conversion layer 115r and the green conversion layer 115g.

The red conversion layer 115r and the green conversion layer 115g include phosphors (which may include quantum dots). The phosphors convert monochromatic light, e.g., blue light or ultraviolet light, into a desired color. The red conversion layer 115r includes, e.g., phosphors that convert blue light into red light and is formed in the red pixel region 140r. The green conversion layer 115g includes phosphors that convert blue light into green light and is formed in the green pixel region 140g. In an embodiment, since blue micro LEDs are used as the light emitting elements 121, the color conversion layer 115 is not used for the blue pixel region 140b.

In an embodiment, the light transmissive layer 115b is formed instead of the color conversion layer 115 in the blue pixel region 140b. The light emitting elements 121 of the embodiment are blue micro LEDs, and the color filter 113 and the color conversion layer 115 are not used in the blue pixel region 140b. In the embodiment, for the blue pixel region 140b, the light transmissive layer 115b is formed in a portion of the blue pixel region 140b to obtain the same thickness as other color pixel regions. The light transmissive layer 115b may use the same material as the forming material of the light transmissive resin layer 116. Further, a resin applicable to the color conversion layer 115 has a refractive index of about 1.3 or more and about 1.7 or less.

Further, when the light emitting elements 121 emit ultraviolet light, the color conversion layer 115 may be used instead of the light transmissive layer 115b for the blue pixel region 140b as well. Further, a blue color filter may be used for a portion of the blue pixel region 140b. Further, the blue pixel region 140b may maintain a gap without forming the light transmissive layer 115b, or may be filled with a bonding material of the bonding unit 130, etc.

A thickness of the red conversion layer 115r, the green conversion layer 115g, and the light transmissive layer 115b is 5 μm or more and 50 μm or less. The thickness of each layer is appropriately set according to a height of the pixel region 140 (i.e., the height of the partition walls 114) so as to fit within the pixel region 140 partitioned by the partition walls 114.

The light transmissive resin layer 116 is a layer interposed between the color conversion layer 115 and the reflective layer 117. The light transmissive resin layer 116 may be configured to transmit light toward the transparent substrate 111 when emission light from the light emitting elements 121 and color-converted light that has passed through the color conversion layer 115 are reflected at the reflective layer 117 and incident between the color conversion layer 115 and the reflective layer 117. The light transmissive resin layer 116 is disposed between the color conversion layer 115 and the reflective layer 117 and, when emission light from the light emitting elements 121 and color-converted light that has passed through the color conversion layer 115 are reflected at the reflective layer 117 between the color conversion layer 115 and the reflective layer 117, it may enhance luminous efficiency in a light guide direction (a display surface side of the display device 100, a direction from the light emitting elements 121 toward the transparent substrate 111 along the Z-axis direction). A thickness of the light transmissive resin layer 116 is about 2 μm or more and about 20 μm or less.

A forming material of the light transmissive resin layer 116 is a resin having a refractive index of about 1.25 or more and light transmissivity with a transmittance of about 70% or more and about 100% or less, and for example, acrylic resins, epoxy-based resins, silicone resins and/or mixtures thereof, fluorine resins having photocurability and/or thermosetting properties, etc. may be suitably used.

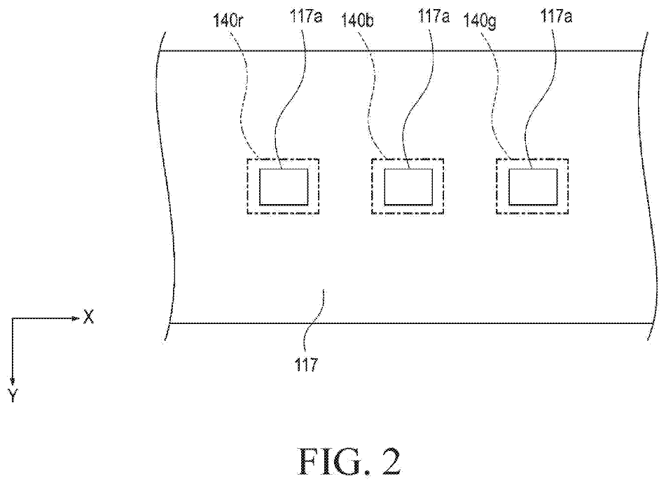

The reflective layer 117 is formed on the light transmissive resin layer 116. The reflective layer 117 has openings 117a as illustrated in FIG. 2. The openings 117a have an opening size equal to or greater than the element size of the light emitting elements 121 when viewed in a plan view. The opening size of the openings 117a is equal to or greater than the element size of the light emitting elements 121 when viewed in a plan view to not obstruct incidence of light emitted from the light emitting elements 121 into the pixel regions 140 at least, and is equal to or less than a lower surface size (opening size) of the pixel regions 140 to prevent unnecessary diffuse reflection. In FIG. 2, the opening size of the openings 117a corresponds to an area (opening area) of a region partitioned by a vertical side extending in the X direction and a horizontal side extending in the Y direction. The element size of the light emitting elements 121 is an area within an outer edge of the light emitting elements 121 corresponding to the openings 117a when viewed in a plan view.

The openings 117a are formed at positions where an entire plane of the corresponding light emitting elements 121 faces from the openings 117a when viewed in a plan view. The openings 117a may be formed such that a centroid of the openings 117a viewed in a plan view and a centroid of the light emitting elements 121 viewed in plan coincide in a thickness direction of the display device 100 (a stacking direction of the color conversion structure 110 and the light emitting element array substrate 120 along the Z direction).

A shape of the openings 117a is not particularly limited and may be polygonal or circular in addition to rectangular. The openings 117a may be appropriately designed based on a planar shape of the corresponding light emitting elements 121 or a lower surface shape of the pixel regions 140. Further, ends of the openings 117a may contact the light transmissive resin layer 116 formed in the corresponding pixel regions 140, and may contact edge portions of the partition walls 114 without contacting the light transmissive resin layer 116.

Since the reflective layer 117 has the openings 117a corresponding to the light emitting elements 121, backward reflected light where light emitted from the light emitting elements 121 reflects from the surface of the color conversion layer 115, or light of backward emission where color-converted light that has passed through the color conversion layer 115 emits on the light emitting element 121 side, may be reflected toward the light guide direction and recycled. Therefore, the display device 100 may reflect light that may cause light loss such as backward reflected light or backward light toward the light guide direction side to reduce light loss, and may achieve low power consumption while enhancing luminous efficiency. Further, if the reflective layer 117 forms the openings 117a with an opening size equal to or greater than the element size of the corresponding light emitting elements 121 when viewed in plan, light may be recycled more effectively to enhance luminous efficiency.

As a forming material of the reflective layer 117, materials including any one of Al—Al alloy, Ag—Ag alloy, Cu—Cu alloy, Pd—Pd alloy, Rh, TiO₂ mixed resin, and Al₂O₃ mixed resin, etc. may be suitably used. A resin included in the TiO₂ mixed resin or Al₂O₃ mixed resin may be the same as types of resins that may be included in the light transmissive resin layer 116. For example, a resin included in the TiO₂ mixed resin or Al₂O₃ mixed resin included in the forming material of the reflective layer 117 may be a resin having a refractive index of about 1.25 or more and light transmissivity with a transmittance of about 70% or more and about 100% or less. For example, a resin included in the TiO₂ mixed resin or Al₂O₃ mixed resin included in the forming material of the reflective layer 117 may include acrylic resins, epoxy-based resins, silicone resins and/or mixtures thereof, fluorine resins having photocurability and/or thermosetting properties, etc.

A thickness of the reflective layer 117 is 50 nm or more in the vertical direction (Z direction). The thickness of the reflective layer 117 may be appropriately set according to product specifications of the display device 100.

On the light emitting element array substrate 120, thin film transistors (TFTs), line layers, etc. are formed, and the light emitting elements 121 are mounted. In an embodiment, the light emitting elements 121 are monochromatic light emitting elements such as micro LEDs. The micro LEDs emit, e.g., blue light or ultraviolet light. The emitted blue light or ultraviolet light is converted to a desired color by the color conversion layer 115.

The light emitting element array substrate 120 may be appropriately formed including an anisotropic conductive film (ACF), conductive adhesive, solder, metal bumps formed of copper or aluminum, bump plating by electroplating, etc. as necessary when mounting the light emitting elements 121.

The bonding unit 130 bonds the color conversion structure 110 and the light emitting element array substrate 120. The bonding unit 130 is formed to be interposed between the color conversion structure 110 and the light emitting element array substrate 120 to bond both. A thickness of the bonding unit 130 is about 5 μm or less in the vertical direction (Z direction).

The bonding unit 130 is formed of a bonding material such as an adhesive or adhesive agent. As the bonding material, e.g., transparent epoxy resins and silicone resins, etc. may be suitably used.

Next, a manufacturing method of the display device 100 according to an embodiment is described.

The color conversion structure 110 is manufactured, e.g., as follows. A black resist is applied on the transparent substrate 111, and the light-shielding matrix 112 (black matrix) for pixel separation is formed using a photolithography process.

The partition walls 114 are formed using a photolithography process to form the pixel regions 140 of red, green, and blue that become subpixels. The red color filter 113r and the green color filter 113g are formed in the red pixel region 140r and the green pixel region 140g using a photolithography process. Further, as necessary, an overcoat layer may be applied from above the red color filter 113r and the green color filter 113g. As a result, a substrate surface may be planarized by the overcoat layer.

A resin having phosphors is filled and cured (thermally cured and/or UV cured) in regions of the red pixel region 140r and the green pixel region 140g surrounded by the partition walls 114 to form the color conversion layer 115. The red conversion layer 115r that converts light emitted from the light emitting elements 121 to red is formed in the red pixel region 140r. The green conversion layer 115g that converts light emitted from the light emitting elements 121 to green is formed in the green pixel region 140g. Further, a light transmissive resin without phosphors is filled and cured (thermally cured and/or UV cured) in portions of the blue pixel region 140b and the color conversion layer 115 surrounded by the partition walls 114 to form the light transmissive layer 115b and the light transmissive resin layer 116.

The reflective layer 117 is formed on surfaces of the partition walls 114 and the light transmissive resin layer 116 using a sputtering process, and the openings 117a equal to or greater than the element size of the light emitting elements 121 are patterned to match arrangement positions of the light emitting elements 121.

The color conversion structure 110 may be formed as described above.

For bonding the color conversion structure 110 and the light emitting element array substrate 120, a bonding material that becomes the bonding unit 130 is applied on the light emitting element array substrate 120. On the light emitting element array substrate 120 used, TFTs, line layers, etc. are formed, and micro LED chips are mounted as the light emitting elements 121. The light emitting element array substrate 120 may be formed by mounting micro LEDs through known formation processes. The color conversion structure 110 is positioned and overlapped on the surface of the light emitting element array substrate 120 coated with the bonding material, and bonded by pressing in a direction to bring both closer under decreased pressure. Thereafter, energy such as heat or ultraviolet light is applied to cure the bonding material. In this case, light emission from LEDs on the light emitting element array substrate 120 may also be used.

As described above, the display device 100 for full-color display may be manufactured.

The display device 100 of the first embodiment provides the reflective layer 117 having the openings 117a corresponding to the light emitting elements 121 of each color pixel on the light transmissive resin layer 116 formed on the color conversion layer 115, and therefore may reflect the above-described backward reflected light, backward light, etc. toward the light guide direction side for recycling. Therefore, the display device 100A may reduce light loss and achieve relatively low power consumption while enhancing luminous efficiency.

Next, a display device 100A of a second embodiment is described. In the description of the second embodiment, mainly differences from the above-described embodiment is described, and components having the same functions as other embodiments are given the same or related reference numerals, detailed descriptions are omitted, and not specifically mentioned. Further, configurations, members, usage methods, etc. may be the same as in the first embodiment.

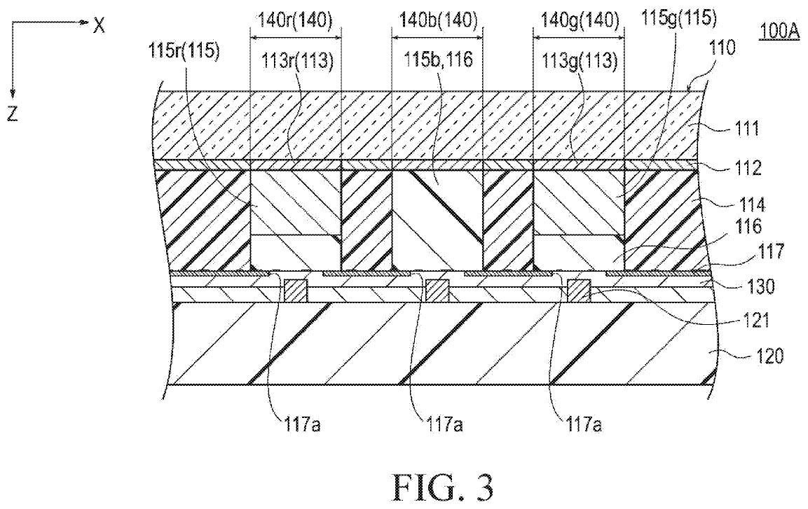

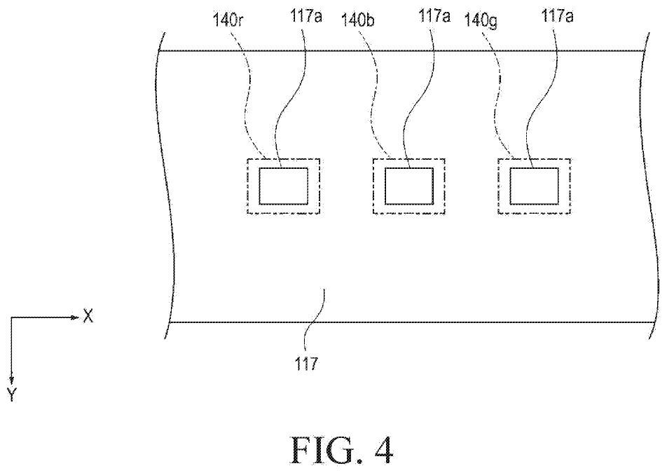

FIG. 3 is a cross-sectional view illustrating a configuration of the display device 100A according to the second embodiment, and FIG. 4 is a view illustrating the color conversion structure 110 of the display device 100A according to the second embodiment as viewed from the reflective layer 117 side.

In the display device 100A of the second embodiment, the red conversion layer 115r that becomes the color conversion layer 115 and the light transmissive resin layer 116 are stacked and formed in the red pixel region 140r surrounded by and/or adjacent to the partition walls 114, the green conversion layer 115g and the light transmissive resin layer 116 are stacked and formed in the green pixel region 140g, and the light transmissive resin layer 116 functioning as the light transmissive layer 115b is formed in the blue pixel region 140b.

The display device 100A differs from the first embodiment in that the color conversion layer 115 and the light transmissive resin layer 116 are filled in the pixel regions 140.

In the display device 100A, as illustrated in FIG. 3, the reflective layer 117 is formed so that the openings 117a are disposed on a lower surface of the light transmissive resin layer 116.

The display device 100A of the second embodiment forms the light transmissive resin layer 116 in the pixel regions 140 of each color pixel, and includes the reflective layer 117 having the openings 117a similar to the display device 100 of the first embodiment as illustrated in FIG. 4, and therefore may reflect backward reflected light, backward light, etc. toward the light guide direction side to recycle light. Therefore, the display device 100A may reduce light loss and achieve low power consumption while enhancing luminous efficiency. Further, since the display device 100A forms the light transmissive resin layer 116 in each pixel region 140, light emitted from the light emitting elements 121 corresponding to each pixel region 140 is less likely to enter adjacent pixel regions 140, thereby reducing color mixing.

The display devices 100, 100A of embodiments may also be implemented with appropriate modifications as in the following modifications. Further, in the description of the following modifications, mainly differences from the above-described embodiments is described, and components having the same functions as other embodiments are given the same or related reference numerals, detailed descriptions are omitted, and not specifically mentioned. Further, configurations, members, usage methods, etc. may be the same as in each embodiment. Further, each modification may also be implemented in combination with other embodiments by appropriately selecting necessary configurations from among the configurations illustrated in each modification within a range not departing from the gist of the present invention.

A display device 100B of a third embodiment is described.

The display device 100B of the third embodiment is a form in which a portion of the display device 100A of the first embodiment is modified and an optical functional layer 150, etc. are added.

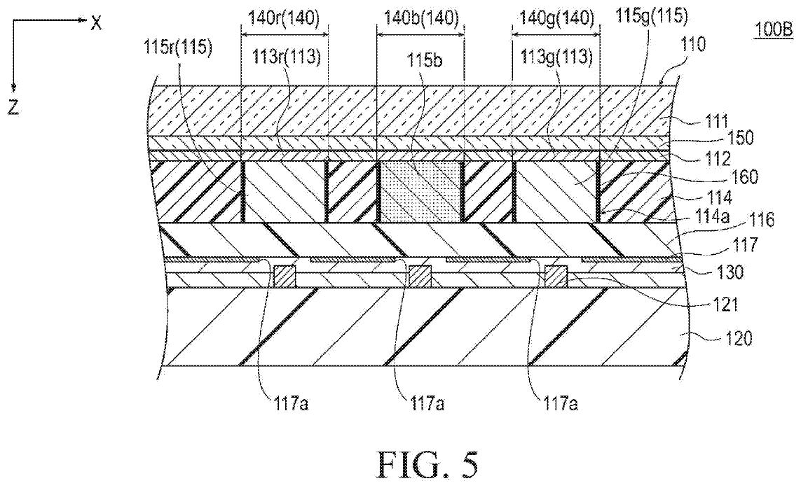

The display device 100B includes the color conversion structure 110, the light emitting element array substrate 120, and the bonding unit 130 as illustrated in FIG. 5. The color conversion structure 110 and the light emitting element array substrate 120 are bonded in a vertically aligned state by the bonding unit 130.

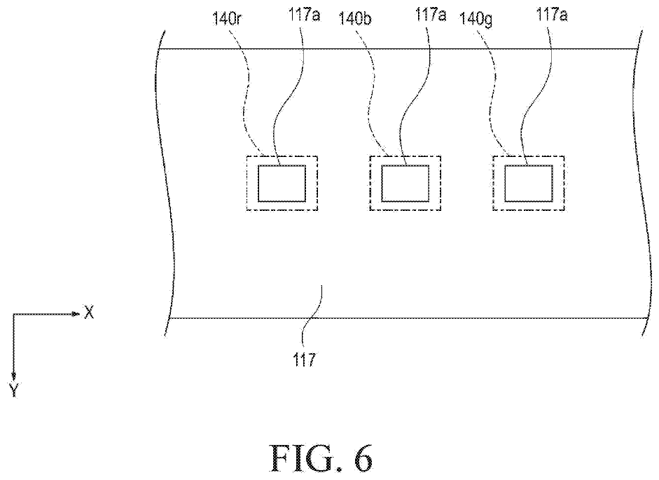

As illustrated in FIGS. 5 and 6, the color conversion structure 110 includes the transparent substrate 111, the light-shielding matrix 112, the color filters 113 (the red color filter 113r, the green color filter 113g), the partition walls 114, the color conversion layers 115 (the red conversion layer 115r, the green conversion layer 115g), the light transmissive layer 115b including light diffusion particles, the light transmissive resin layer 116, the reflective layer 117 having the openings 117a, the optical functional layer 150, and reflective portions 160.

The optical functional layer 150 is composed of an overcoat layer and/or an air layer formed of a low refractive index material having a refractive index of about 1.0 or more and about 1.3 or less. The optical functional layer 150 may be configured to include at least one of an overcoat layer and an air layer. A thickness of the optical functional layer 150 is about 3 μm or less in the vertical direction (Z direction) for both the overcoat layer and air layer, but may be formed to be thinner while maintaining functional characteristics.

The optical functional layer 150 may return color-converted light at angles that may not be emitted from the color conversion layer 115 back to the color conversion layer 115 to convert it to an angle that may be emitted. Therefore, the display device 100B further enhances the light recycling effect.

The display device 100B has the reflective portions 160 on inner circumferential surfaces 114a (side surfaces partitioned into the pixel regions 140) of the partition walls 114. The reflective portions 160 may be formed using constituent materials of the reflective layer 117. The reflective portions 160 may form smooth surfaces with uniform thickness over the entire surface of the inner circumferential surfaces 114a, or may form surfaces having uneven shapes partially or entirely. From the viewpoint of enhancing reflection efficiency, the reflective portions 160 may be formed as smooth surfaces covering and/or provided on the entire periphery of the inner circumferential surfaces 114a. By including the reflective portions 160, the display device 100B enhances reflection efficiency within the pixel regions 140 and enhances luminous efficiency of color-converted light, etc.

The display device 100B includes light diffusion particles having a light diffusion effect in the light transmissive layer 115b filled in the blue pixel region 140b. The light diffusion particles may be any known material that is applicable to the display device 100B and may exhibit a light diffusion effect. Thereby, the display device 100B may enhance viewing angle characteristics.

Since the display device 100B of the third embodiment has the optical functional layer 150 and the reflective portions 160 on the inner circumferential surfaces 114a of the partition walls 114, color-converted light that has passed through the color conversion layer 115 may be more effectively recycled to achieve better enhancement in luminous efficiency while achieving relatively low power consumption.

A display device 100C of a fourth embodiment is described.

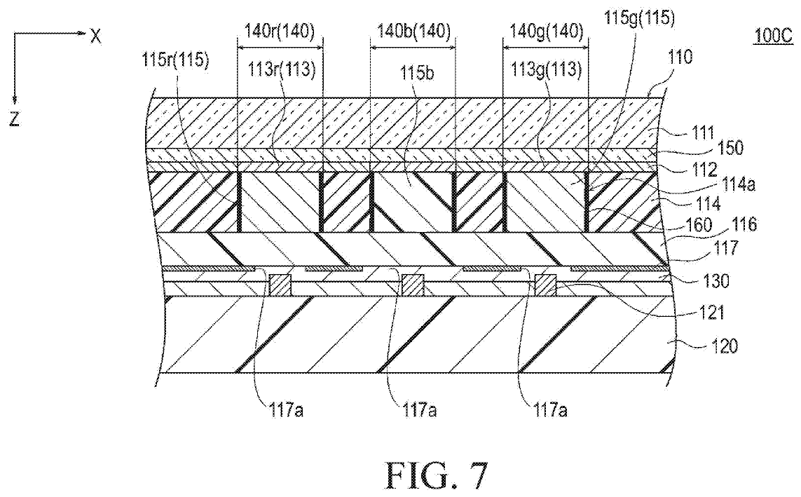

As illustrated in FIG. 7, the display device 100C of the fourth embodiment is a form in which, in the display device 100B of the third embodiment, only constituent resin of the light transmissive resin layer 116 is applied to the light transmissive layer 115b, and the reflective layer 117 is formed so as not to overlap the blue pixel region 140b.

As illustrated in FIG. 7, the display device 100C includes the color conversion structure 110, the light emitting element array substrate 120, and the bonding unit 130. The color conversion structure 110 and the light emitting element array substrate 120 are bonded in a vertically aligned state by the bonding unit 130.

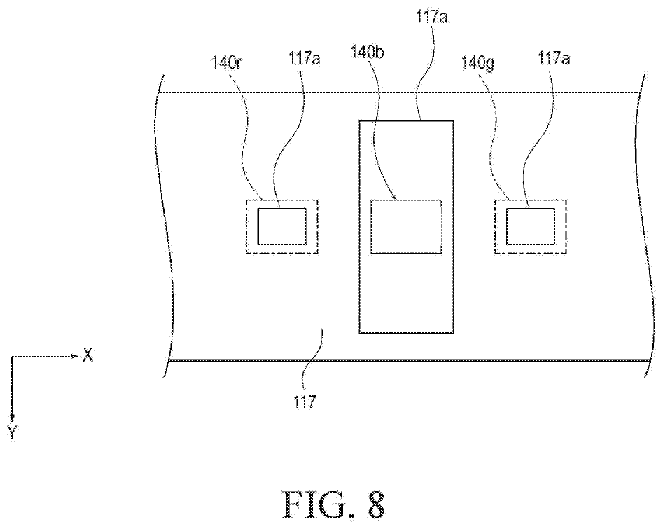

As illustrated in FIGS. 7 and 8, the color conversion structure 110 includes the transparent substrate 111, the light-shielding matrix 112, the color filters 113 (the red color filter 113r, the green color filter 113g), the partition walls 114, the color conversion layers 115 (the red conversion layer 115r, the green conversion layer 115g), the light transmissive layer 115b, the light transmissive resin layer 116, the reflective layer 117 having the openings 117a, the optical functional layer 150, and the reflective portions 160.

By forming the reflective layer 117 so as not to overlap the blue pixel region 140b as illustrated in FIG. 8, the display device 100C of the fourth embodiment may make an area of the opening 117a for the blue pixel region 140b larger compared to other openings 117a. Therefore, the display device 100C may efficiently make emission light from the light emitting elements 121 for the blue pixel region 140b incident, thereby enhancing luminous efficiency.

A display device 100D of a fifth embodiment is described.

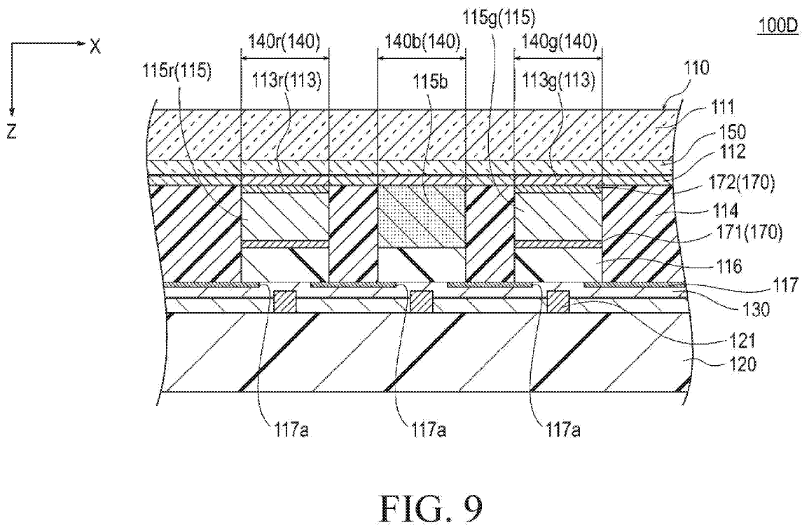

As illustrated in FIG. 9, the display device 100D of the fifth embodiment is a form in which, in the display device 100A of the second embodiment, the optical functional layer 150 is added, the height of the partition walls 114 is extended to fill the color conversion layer 115 and the light transmissive resin layer 116 in each pixel region 140, light diffusion particles are included in the light transmissive layer 115b, and optical filters 170 are formed on an upper surface and/or a lower surface of the red conversion layer 115r in the red pixel region 140r and on an upper surface and/or a lower surface of the green conversion layer 115g in the green pixel region 140g.

As illustrated in FIG. 9, the display device 100D includes the color conversion structure 110, the light emitting element array substrate 120, and the bonding unit 130. The color conversion structure 110 and the light emitting element array substrate 120 are bonded in a vertically aligned state by the bonding unit 130.

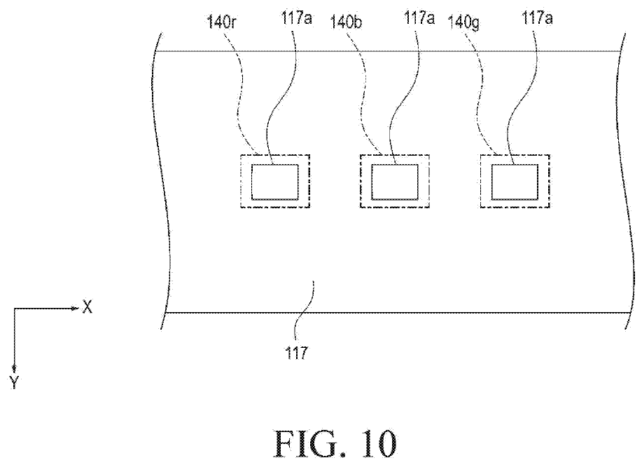

As illustrated in FIGS. 9 and 10, the color conversion structure 110 includes the transparent substrate 111, the light-shielding matrix 112, the color filters 113 (the red color filter 113r, the green color filter 113g), the partition walls 114, the color conversion layers 115 (the red conversion layer 115r, the green conversion layer 115g), the light transmissive layer 115b including light diffusion particles, the light transmissive resin layer 116, the reflective layer 117 having the openings 117a, the optical functional layer 150, the reflective portions 160, and the optical filters 170.

The optical filters 170 may be dichroic filters that reflect light in specific wavelength regions and transmit the remaining wavelength regions. The optical filters 170 include first optical filters 171 that transmit emission light (blue light) from the light emitting elements 121 and reflect green or red light, and second optical filters 172 that reflect emission light (blue light) from the light emitting elements 121 and transmit green light or red light. A thickness of the optical filters 170 is about 5 μm or less, and may be relatively thin under the assumption that optical characteristics are ensured.

The first optical filters 171 are formed on surfaces (lower surfaces) of the red conversion layer 115r and the green conversion layer 115g on the light emitting element 121 side. The second optical filters 172 are formed on surfaces (upper surfaces) of the red conversion layer 115r and the green conversion layer 115g on the transparent substrate 111 side.

The first optical filters 171 and the second optical filters 172 may be formed on two opposite sides of the red conversion layer 115r and the green conversion layer 115g, or only one of them may be formed.

Since the display device 100D of the fifth embodiment has the optical filters 170, color-converted light may be more effectively recycled to achieve low power consumption while enhancing luminous efficiency.

A display device 100E of sixth embodiment is described.

The display device 100E of sixth embodiment is a form in which the height of the partition walls 114 of the display device 100B of the third embodiment is extended, and the color conversion layer 115 and the light transmissive resin layer 116 are filled in each pixel region 140.

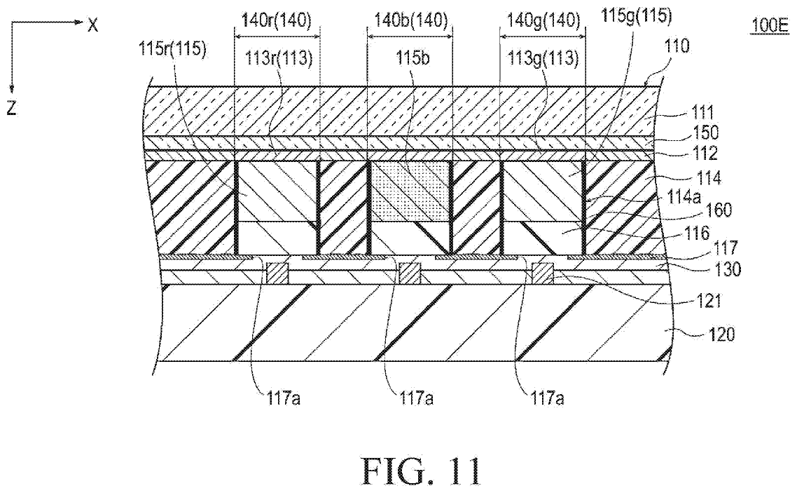

As illustrated in FIG. 11, the display device 100E includes the color conversion structure 110, the light emitting element array substrate 120, and the bonding unit 130. The color conversion structure 110 and the light emitting element array substrate 120 are bonded in a vertically aligned state by the bonding unit 130.

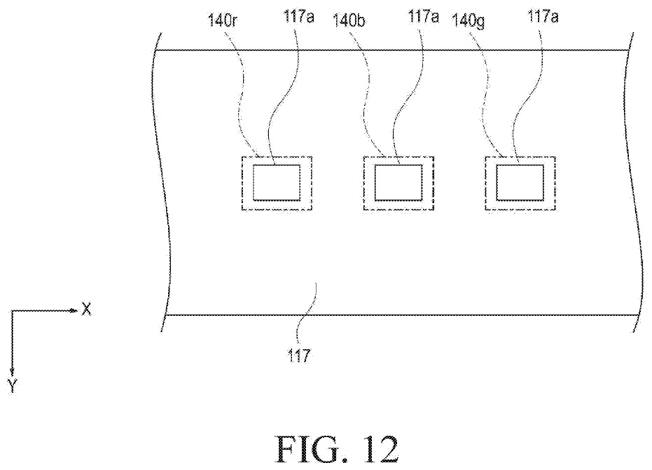

As illustrated in FIGS. 11 and 12, the display device 100E includes the transparent substrate 111, the light-shielding matrix 112, the color filters 113 (the red color filter 113r, the green color filter 113g), the partition walls 114, the color conversion layers 115 (the red conversion layer 115r, the green conversion layer 115g), the light transmissive layer 115b including light diffusion particles, the light transmissive resin layer 116, the reflective layer 117 having the openings 117a, the optical functional layer 150, and the reflective portions 160.

Since the display device 100E of the sixth embodiment has the optical functional layer 150 and the reflective portions 160 on the inner circumferential surfaces 114a of the partition walls 114, color-converted light that has passed through the color conversion layer 115 may be more effectively recycled to achieve low power consumption while enhancing luminous efficiency.

As described above, the display device 100 according to an embodiment has the light emitting element array substrate 120 having the plurality of light emitting elements 121, the color conversion structure 110 disposed on the light emitting element array substrate 120, and the bonding unit 130 bonding the light emitting element array substrate 120 and the color conversion structure 110, wherein the color conversion structure 110 includes the transparent substrate 111, the partition walls 114 partitioning the pixel regions 140 of each color pixel of red pixels, green pixels, and blue pixels on the transparent substrate 111, the color conversion layer 115 formed in at least one of the pixel regions 140 of each color pixel and converting light incident on the pixel region 140 into a color corresponding to each color pixel, the light transmissive resin layer 116 formed on the color conversion layer 115, and the reflective layer 117 formed on the light transmissive resin layer 116 and having the openings 117a formed corresponding to each pixel to guide light from the light emitting elements 121 into the partition walls 114 of each color pixel.

With this configuration, the display device 100 may reduce light loss due to backward reflected light where light emitted from the light emitting elements 121 reflects from the surface of the color conversion layer 115 or backward emission of color-converted light, thereby implementing enhancement in luminous efficiency and low power consumption.

The effects of embodiments and related embodiments are provided as follows. However, the technical scope of the present disclosure is not limited to the following embodiments.

In the following evaluation tests, output performance of the display device according to embodiments was evaluated.

The evaluation test was conducted as follows. The evaluation test used a simulation software.

In the simulation, the following conditions were set. The sample was formed by stacking a transparent substrate, partition walls, a reflective layer, a bonding unit, and a light emitting element array substrate in order from top to bottom, with a color conversion layer formed within the partition walls.
Transparent substrate: Thickness about 100 μm
Red CF RI: About 1.69
CF opening size: About 74 μm×200 μm
Bonding layer thickness: About 2 μm
Partition walls: About 95% reflective mirror
Opening size: X; about 40 μm, Y; about 25 μm
Partition wall height: About 12 μm

Further, in the simulation, the partition wall height was based on Related Example 1 (without light transmissive resin), and was appropriately extended according to resin height for Examples 1 to 4. Examples 1 to 4 were color conversion structures having partition wall reflection, a reflective layer with openings, and a light transmissive resin formed on the reflective layer. Related Example 1 was a color conversion structure having partition wall reflection, forming a reflective layer with openings, and not forming a light transmissive resin layer. The configuration difference between the comparative example and each example is the presence or absence of the light transmissive resin layer formed under the color conversion layer.

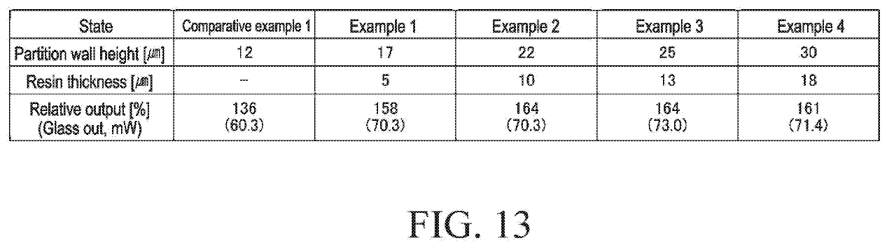

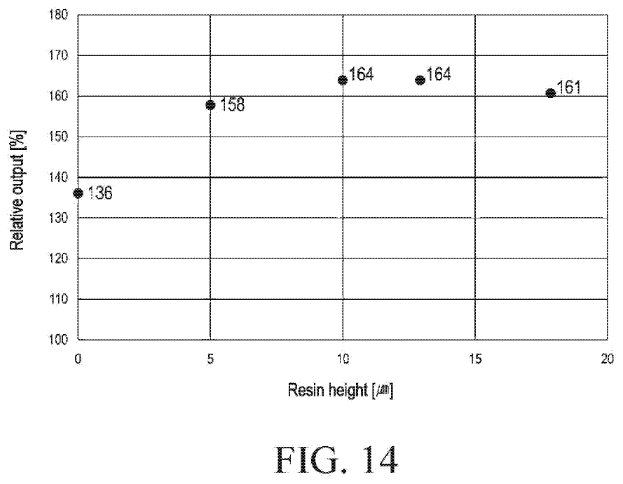

The evaluation results are illustrated in FIG. 13 and FIG. 14. The evaluation results illustrated in FIG. 13 and FIG. 14 show the output efficiency when the output of a sample without a light transmissive resin layer, without a reflective layer, and without partition wall reflection is taken as about 100%.

As illustrated in FIG. 13 and FIG. 14, Related Example 1 had an output of about 136% (60.3 mW). In contrast, Examples 1 to 4 had outputs of about 158% (about 70.3 mW) to about 164% (about 73.0 mW), with Example 2 (partition wall height about 22 μm, light transmissive resin layer thickness (resin thickness) about 10 μm) and Example 3 (partition wall height about 25 μm, light transmissive resin layer thickness about 13 μm) both having the highest output efficiency at about 164% output. From the results of Related Example 1 and Examples 1 to 4, it could be identified that forming a reflective layer with openings and reflective portions on partition walls is effective for enhancing output efficiency in a display device.

The structural difference between Examples 1 to 4 and the related example is the presence or absence of the light transmissive resin layer. In this regard, as in Examples 1 to 4, by forming a light transmissive resin layer between the color conversion layer and the reflective layer, it could be identified that backward reflected light, etc. of light emitted from the light emitting elements is more efficiently recycled through the light transmissive resin layer and reflective layer, further enhancing output efficiency.

As described above, since the display device according embodiment include the reflective layer having openings and the light transmissive resin layer formed on the reflective layer, backward reflected light from the light emitting elements, color-converted light that has passed through the color conversion layer, etc. may be effectively recycled, and light loss may be decreased to enhance luminous efficiency while achieving low power consumption.

While embodiments have been described with reference to the figures, it will be understood by those of ordinary skill in the art that various changes in form and details may be made therein without departing from the spirit and scope as defined by the following claims and their equivalents.

What is claimed is:

1. A display device comprising:
a light emitting element array substrate comprising a plurality of light emitting elements;
a color conversion structure on the light emitting element array substrate; and
a bonding unit between the light emitting element array substrate and the color conversion structure,
wherein the color conversion structure comprises:
a transparent substrate;
partition walls between pixel regions of a plurality of color pixels and on the transparent substrate;
a color conversion layer in at least one pixel region of the pixel, the color conversion layer being configured to convert light incident on the at least one pixel region into a color corresponding to a color pixel in the at least one pixel region;
a light transmissive resin layer on the color conversion layer; and
a reflective layer on the light transmissive resin layer, the reflective layer comprising openings corresponding to each color pixel of the plurality of color pixels and configured to guide light from the light emitting elements into the partition walls.

2. The display device of claim 1, wherein a size of at least one opening of the openings is equal to or greater than a size of the light emitting element in a plan view.

3. The display device of claim 1, wherein the reflective layer comprises at least one of Al—Al alloy, Ag—Ag alloy, Cu—Cu alloy, Pd—Pd alloy, Rh, TiO₂ mixed resin, and Al₂O₃ mixed resin.

4. The display device of claim 1, wherein a transmittance of the light transmissive resin layer is greater than or equal to 70% and less than or equal to 100%.

5. The display device of claim 1, wherein a light transmissive resin mixed with light diffusion particles fills the pixel region corresponding to the blue pixel.

6. The display device of claim 1, wherein an inner circumferential surface of at least one partition wall of the partition walls comprises a reflective portion that comprises at least one of Al—Al alloy, Ag—Ag alloy, Cu—Cu alloy, Pd—Pd alloy, Rh, TiO₂ mixed resin, and Al₂O₃ mixed resin.

7. The display device of claim 1, wherein an optical functional layer comprising at least one of an overcoat layer having a refractive index greater than or equal to 1.0 and less than or equal to 1.3 and an air layer is between the color conversion layer and the transparent substrate.

8. The display device of claim 1, wherein the reflective layer is spaced apart from the pixel region of the blue pixel in a horizontal direction.

9. The display device of claim 1, wherein a first optical filter is between the color conversion layer and the light emitting element, the first optical filter being configured to transmit blue light and reflect green light and red light.

10. The display device of claim 1, wherein a second optical filter is between the color conversion layer and the transparent substrate, the second optical filter being configured to reflect blue light and transmit green light and red light.

11. The display device of claim 1, wherein the color conversion layer and the light transmissive resin layer are in the pixel region partitioned by the partition walls corresponding to at least one pixel among each color pixel.

12. The display device of claim 1, wherein a height of at least one partition wall of the partition walls is greater than or equal to 5 μm and less than or equal to 50 μm, and a thickness of the light transmissive resin layer is greater than or equal to 2 μm and less than or equal to 20 μm.

13. The display device of claim 1, wherein the light emitting element is a micro light emitting diode (LED).
